(19) United States
(12) Patent Application Publication
(10) Pub. No.: US 2020/0287545 A1
(43) Pub. Date: Sep. 10, 2020

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hironori Nagasawa, Yokohama Kanagawa (JP)

(21) Appl. No.: 16/564,329

(22) Filed: Sep. 9, 2019

(30) Foreign Application Priority Data
Mar. 7, 2019 (JP) 2019-041562

(51) Int. Cl. H03K 19/0185; H03K 17/687; H03K 17/693

(52) U.S. Cl. CPC H03K 19/018521; H03K 17/693; H03K 17/6872; H03K 19/018557

(57) ABSTRACT

According to one embodiment, a semiconductor device includes: a first circuit transmitting a first signal; a second circuit receiving a second signal; a first level shift circuit converting a signal level of the first signal from a value corresponding to a first voltage to a value corresponding to a second voltage different from the first voltage, and transmitting the second signal; and a third circuit receiving the first signal and a control signal, and transmitting a third signal having a fixed signal level to the first level shift circuit when a signal level of the control signal is a first level.

### CROSS-REFERENCE TO RELATED APPLICATIONS

This application is based upon and claims the benefit of priority from Japanese Patent Application No. 2019-041562, filed Mar. 7, 2019, the entire contents of which are incorporated herein by reference.

### FIELD

Embodiments described herein relate generally to a semiconductor device.

### BACKGROUND

Various circuit configurations and control methods have been researched and developed to improve the characteristics of semiconductor devices.

### BRIEF DESCRIPTION OF THE DRAWINGS

FIG. 1 is a diagram schematically showing the entire configuration of a semiconductor device of the first embodiment.

FIG. 2, FIG. 3, FIG. 4, FIG. 5, FIG. 6 and FIG. 7 are diagrams showing the internal configuration of the semiconductor device of the first embodiment.

FIG. 8 is a diagram showing an operation example of the semiconductor device of the first embodiment.

FIG. 9 is a graph for illustrating the semiconductor device of the first embodiment.

FIG. 10 is a diagram showing an internal configuration of a semiconductor device of the second embodiment.

FIG. 11 is a diagram for illustrating the semiconductor device of the second embodiment.

FIG. 12 is a diagram showing an internal configuration of a semiconductor device of the third embodiment.

FIG. 13 is a diagram showing an internal configuration of a semiconductor device of the fourth embodiment.

FIG. 14 is a diagram showing an example of how a semiconductor device of an embodiment is applied.

### DETAILED DESCRIPTION

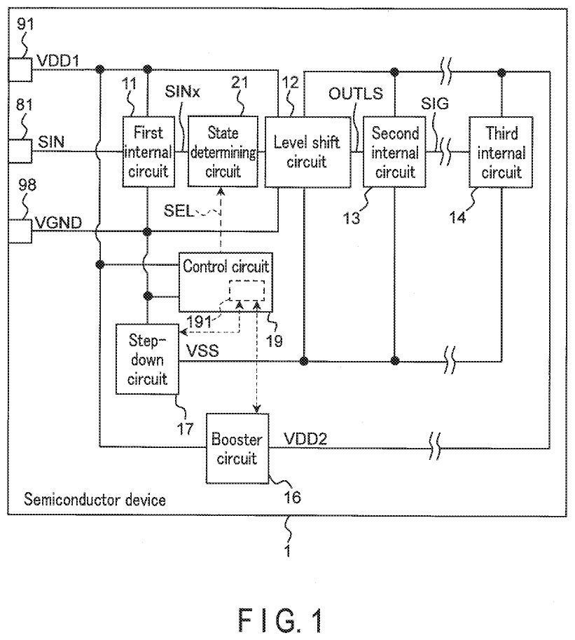

Semiconductor devices of embodiments will be described with reference to FIGS. 1 to 14.

Hereinafter, the embodiments will be described in detail with reference to the accompanying drawings. In the description below, elements having the same functions and configurations will be denoted by the same reference symbols.

In the embodiments described below, where constituent elements denoted by reference symbols to which numbers/letters are attached at the end for discrimination (e.g., logic circuits, various voltages and signals) do not have to be discriminated from each other, reference symbols without the numbers/letters at the end will be used.

In general, according to one embodiment, a semiconductor device includes: a first circuit transmitting a first signal; a second circuit receiving a second signal; a first level shift circuit converting a signal level of the first signal from a value corresponding to a first voltage to a value corresponding to a second voltage which is different from the first voltage, and transmitting the second signal; and a third circuit receiving the first signal and a control signal, and transmitting a third signal having a fixed signal level to the first level shift circuit when a signal level of the control signal is a first level.

### (1) First Embodiment

A semiconductor device of the first embodiment will be described with reference to FIGS. 1 to 9.

(a) Configuration Example

A configuration example of the semiconductor device of the present embodiment will be described with reference to FIGS. 1 to 7.

FIG. 1 is a schematic diagram showing the entire configuration of the semiconductor device of the present embodiment.

As shown in FIG. 1, the semiconductor device 1 of the present embodiment includes a first internal circuit 11, a level shift circuit 12, a second internal circuit 13, a third internal circuit 14, a booster circuit 16, a step-down circuit 17, an state determining circuit 21, a control circuit 19, etc.

The first internal circuit (semiconductor circuit) 11 receives signal SIN (e.g., data) supplied from the outside of the semiconductor device 1 through terminal 81. Power supply voltage VDD1 is applied to the first internal circuit 11 via power supply terminal 91. Power supply voltage VDD1 is a positive voltage. Power supply voltage VGND is applied to the first internal circuit 11 via power supply terminal 98. Power supply voltage VGND is a reference potential and is, for example, 0V. In the description below, voltage VGND of 0V will be referred to as a ground potential (or ground voltage). Voltage VGND may be a voltage lower than 0V (i.e., a negative voltage). For example, power supply voltage VDD1 and ground potential VGND are supplied from the outside of the semiconductor device 1 (for example, a power supply or another device).

The first internal circuit 11 outputs signal SIN or a processing result using signal SIN as signal SINx at a signal level (voltage value) corresponding to power supply voltage VDD1 or ground potential VGND.

The level shift circuit 12 receives signal INLS of the signal level (voltage value) corresponding to voltage VDD1 or voltage VGND from the first internal circuit 11 through the state determining circuit 21. The level shift circuit 12 converts the voltage value of the signal level of signal INLS from the first internal circuit 11 into a value corresponding to voltage VDD2 or voltage VSS. The level shift circuit 12 outputs signal OUTLS obtained by converting the voltage value of signal INLS.

The second internal circuit 13 receives signal OUTLS from the level shift circuit 12. Power supply voltage VDD2 is applied to the second internal circuit 13. Power supply voltage VDD2 is a positive voltage. Power supply voltage VSS is applied to the second internal circuit 13. Power supply voltage VSS is, for example, a negative voltage or 0V.

The second internal circuit 13 executes calculation processing and/or control operation using signal OUTLS. The second internal circuit 13 outputs signal SIG. Signal SIG is a signal indicating a result of the calculation processing and/or a signal used for control operation.

The third internal circuit 14 receives signal SIG from the second internal circuit 13. The third internal circuit 14 executes calculation processing and/or control operation using signal SIG. For example, second power supply voltage VDD2 and voltage VSS are applied to the third internal circuit 14.

The internal circuits 11, 13 and 14 are semiconductor circuits and have a function of executing desired processing such as a logical operation for signals and control based on signals.

In the semiconductor device 1, the booster circuit 16 generates power supply voltage VDD2 using power supply voltage VDD1. For example, the booster circuit 16 boosts power supply voltage VDD1 to obtain power supply voltage VDD2. The booster circuit 16 supplies power supply voltage VDD2 to the level shift circuit 12, the second internal circuit 13, the third internal circuit 14, etc.

The booster circuit 16 is, for example, a booster charge pump circuit. It should be noted that power supply voltage VDD2 is higher than power supply voltage VDD1.

In the semiconductor device 1, the step-down circuit 17 generates voltage VSS, using ground potential VGND (first reference voltage). For example, the step-down circuit 17 steps down ground potential VGND to obtain power supply voltage VSS. The step-down circuit 17 supplies power supply voltage VSS to the level shift circuit 12, the second internal circuit 13, the third internal circuit 14, etc.

The step-down circuit 17 is, for example, a step-down charge pump circuit. For example, power supply voltage VSS is a voltage lower than ground potential VGND (that is, a negative voltage). There may be a case where power supply voltage VSS is equal to or higher than ground potential VGND and equal to or lower than power supply voltage VDD1.

Where the booster circuit 16 and the step-down circuit 17 do not have to be distinguished from each other, these circuits will be called voltage generation circuits.

The control circuit 19 controls the operations of circuits 11, 12, 13, 14, 16, 17 and 21 of the semiconductor device 1. The control circuit 19 can monitor the operating states of the circuits of the semiconductor device 1. The control circuit 19 includes, for example, a monitor circuit 191. The monitor circuit 191 monitors a voltage value of a voltage generated by the booster circuit 16 (the voltage may be hereinafter referred to as a generated voltage, a boosted voltage, or an output voltage), and a voltage value of a voltage generated by the step-down circuit 17 (the voltage may be hereinafter referred to as a generated voltage, a stepped-down voltage, or an output voltage). The control circuit 19 can perform regulation (adjustment to a predetermined voltage value) of the voltage value of each voltage, based on a monitoring result of the monitor circuit 191.

In the semiconductor device 1 of the present embodiment, the state determining circuit 21 is provided between the first internal circuit 11 and the level shift circuit 12. The state determining circuit 21 receives signal SINx from the first internal circuit 11. The state determining circuit 21 receives control signal SEL from the control circuit 19. The state determining circuit 21 transfers signal INLS (and/or a complementary signal of signal INLS) to the level shift circuit 12.

The state determining circuit 21 can control the transfer timing of signal INLS and/or the activation timing of the level shift circuit 12 (the timing at which a power supply voltage is supplied to the level shift circuit 12), in accordance with control signal SEL.

By the activation control of the level shift circuit 12 performed by the state determining circuit 21, the level shift circuit 12 is electrically connected to a terminal to which power supply voltage VDD2 is supplied (and to the booster circuit 16) and/or to a terminal to which voltage VSS is supplied (and to the step-down circuit 17).

The activation process of the semiconductor device 1 of the present embodiment is started by the supply of power supply voltage VDD1 (and ground potential VGND). The activation process of the semiconductor device of the present embodiment is completed when voltages VDD2 and VSS generated by the booster circuit or the step-down circuit reach desired voltage values. After the activation process of the semiconductor device is completed, the semiconductor device 1 can perform a desired operation/function of its internal circuits.

In the description below, the period from the start of the activation process of the semiconductor device to the completion of the activation process (the period from the start of the supply of the power supply voltage to the completion of the generation of the internal voltage) is also referred to as a standby period or a waiting period. For example, the standby period corresponds to the period from the time when power supply voltages VDD1 and VGND are supplied to the semiconductor device 1 to the time when the voltage values voltage VDD2 and/or voltage VSS generated in the semiconductor device 1 reach predetermined voltage values (standard values).

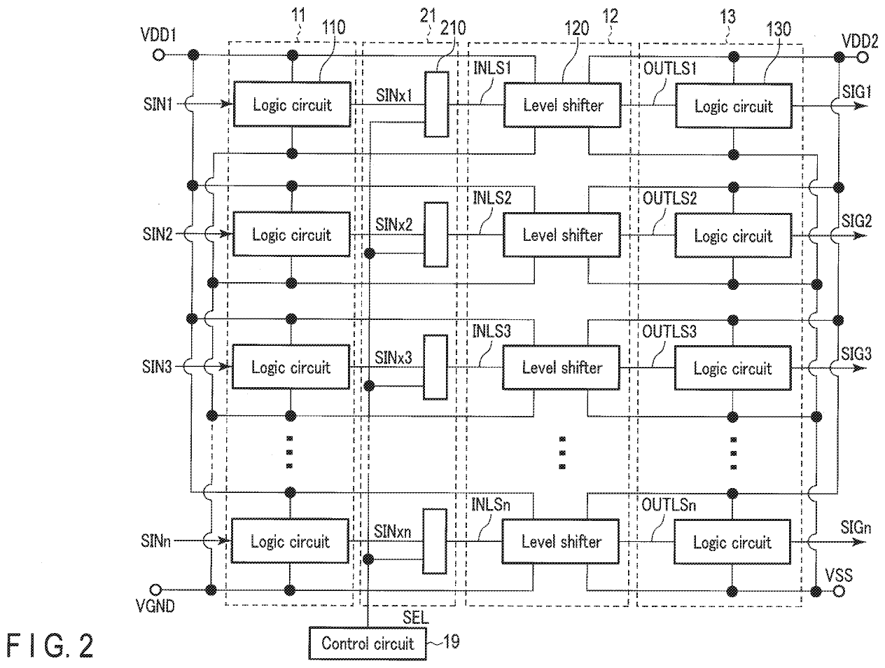

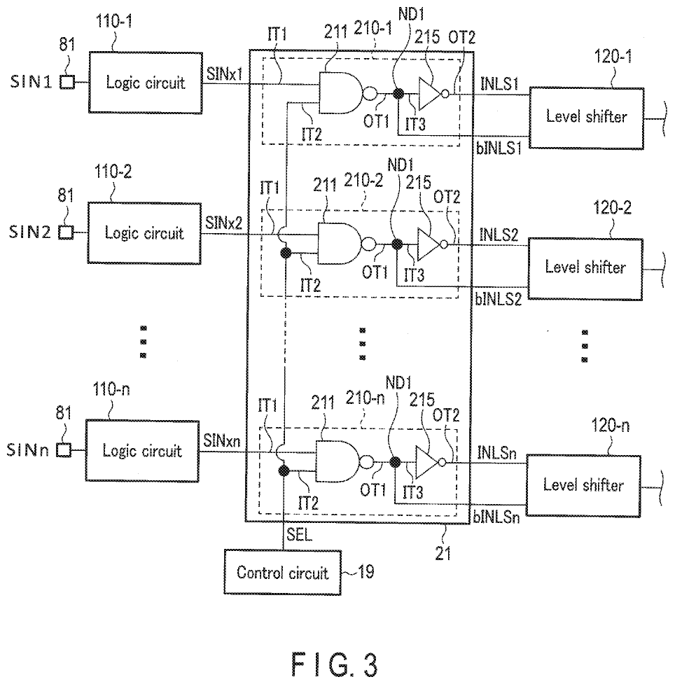

FIG. 2 is a schematic diagram showing an example of the internal configuration of the semiconductor device of the present embodiment.

In FIG. 2, the first internal circuit 11, the state determining circuit 21, the level shift circuit 12, and the second internal circuit 13 are extracted and shown.

As shown in FIG. 2, the first internal circuit 11 includes a plurality of first logic circuits 110. Each of the first logic circuits 110 receives a corresponding one of signals SIN1 to SINn. Power supply voltage VDD1 and ground potential VGND are supplied to each of the first logic circuits 110.

Each of the first logic circuits 110 outputs a signal SINx (SINx1 to SINxn) of either the “H (High)” level or “L (Low)” level according to the signal SIN (SIN1 to SINn) it receives. In the first logic circuits 110, the voltage value of the “H” level signal SIN and SiNx corresponds to the voltage value of power supply voltage VDD1. The voltage value of the “L” level signal SIN and SINx corresponds to the voltage value of ground potential VGND.

The first logic circuit 110 generates “H” level signal using the power supply voltage VDD1 and “L” level signal using the ground voltage VGND. For example, the voltage value of the “H” level signal SIN and SINx is equal to the power supply voltage VDD1. The voltage value of the “L” level signal SIN and SINx is equal to the ground voltage VGND.

The second internal circuit 13 includes a plurality of second logic circuits 130. Each of the second logic circuits 130 receives a corresponding one of signals OUTLS supplied from the level shift circuit 12. Power supply voltage VDD2 and power supply voltage VSS are supplied to each of the second logic circuits 130.

Each of the second logic circuits 130 outputs a signal SIG of either the “H” level or “L” level according to the signal OUTLS it receives. In the second logic circuits 130, the voltage value of the “H” level signal SIG corresponds to the voltage value of power supply voltage VDD2. The voltage value of the “L” level signal SIG corresponds to the voltage value of negative power supply voltage VSS.

The second logic circuit 130 generates “H” level signal using the power supply voltage VDD2 and “L” level signal using the voltage VSS. For example, the voltage value of the “H” level signal OUTLS and SIG is equal to the power supply voltage VDD2. The voltage value of the “L” level signal OUTLS and SIG is equal to the voltage VSS.

It should be noted that the power supply voltage VSS having the same voltage value need not be supplied to all the second logic circuits 130. For example, power supply voltage VSS may be supplied to one or more of the second logic circuits 130, and a power supply voltage different from voltage VSS (for example, ground potential VGND) may be supplied to the remaining ones of the second logic circuits 130. Likewise, power supply voltage VDD2 of the same voltage value need not be supplied to all the second logic circuits 130.

The first and second internal circuits 11 and 13 may be analog circuits or circuits including both of the logic circuit and the analog circuit.

The level shift circuit 12 includes a plurality of level shifters 120. Each of the level shifters 120 is connected to the corresponding one of the first logic circuits 110 via the state determining circuit 21. Each of the level shifters 120 is connected to the corresponding one of the second logic circuits 130. For example, each level shifter 120 shifts the signal level of signal INLS supplied from the corresponding logic gate circuit 210 in the state determining circuit 21 (signal from the first logic circuit 130), and transfers the resultant signal to the corresponding second logic circuit 130 as signal OUTLS.

The signal INLS is generated using the voltage VDD1 or the voltage VGND. For example, the voltage value of the “H” level signal INLS is equal to the power supply voltage VDD1, and the voltage value of the “L” level signal INLS is equal to the voltage VGND.

For example, three or more of power supply voltage VDD1, ground potential VGND, power supply voltage VDD2 and power supply voltage VSS are supplied to each level shifter 120. Each level shifter 120 converts the voltage value corresponding to an “H” level signal from power supply voltage VDD1 to power supply voltage VDD2. Each level shifter 120 converts the voltage corresponding to an “L” level signal from ground potential VGND to power supply voltage VSS.

As described above, in the present embodiment, the state determining circuit 21 is provided between the first internal circuit 11 and the level shift circuit 12.

The state determining circuit 21 includes a plurality of logic gate circuits (also referred to as control units) 210. Each logic gate circuit 210 is connected between the corresponding first logic circuit 110 and the corresponding level shifter 120.

Each logic gate circuit 210 receives signal SINx from the corresponding first logic circuit 110. Each logic gate circuit 210 receives control signal SEL. Control signal SEL is supplied, for example, from the control circuit 19. For example, the signal level of control signal SEL is set to an “H” level or an “L” level based on monitoring results of the magnitude of the output voltage of the booster circuit 16 and/or the step-down circuit 17. For example, each gate circuit 210 operates using power supply voltage VDD1 and ground potential VGND.

As shown in FIG. 2, where control is performed for a plurality of signals SIN (SIN1 to SINn) passed from the first logic circuits 110 to the second logic circuits 130, a plurality of level shifters 120 are controlled using a single voltage generation circuit (the booster circuit 16 and/or the step-down circuit 17). In this case, the semiconductor device 1 of the present embodiment is configured, for example, such that one control circuit 19 is connected to each logic gate circuit 210 so that the control circuit 19 can control the logic gate circuits 210 (the state determining circuit 21) and enables the level shifters 120 to be controlled simultaneously. The control circuit 19 or the voltage generation circuit 16 and 17 may be separately disposed for each group of semiconductor devices and controlled in units of the groups.

(b) Specific Example

A configuration example of a circuit of the semiconductor device of the present embodiment will be described with reference to FIGS. 3 to 7.

<State Determining Circuit>

FIG. 3 is a schematic diagram showing an example of the internal configuration of the state determining circuit of the semiconductor device of the present embodiment.

As shown in FIG. 3, each of logic gate circuits 210 (210-1, 210-2, . . . , 210-n) of the state determining circuit 21 includes a NAND gate 211 and an inverter 215. The NAND gate 211 has two input terminals IT1 and IT2 and one output terminal OT1.

One input terminal IT1 of the NAND gate 211 is connected to the corresponding first logic circuit 110 (110-1, 110-2, . . . , 110-n). The other input terminal IT2 of the NAND gate 211 is connected to the control circuit 19. The output terminal OT1 of the NAND gate 211 is connected to node ND1. Via this node ND1, the output terminal OT1 of the NAND gate 211 is connected to the corresponding level shifter 120 (120-1, 120-2, . . . , 120-n).

The input terminal IT3 of the inverter 215 is connected to node ND1. The output terminal OT2 of the inverter 215 is connected to the corresponding level shifter 120.

Output signal SINx (SINx1 to SINxn) of the logic circuit 110 (110-1 to 110-n) is supplied to input terminal IT1 of each NAND gates 211. Signal SINx corresponds to a processing result for signal SIN in the logic circuit 110. Signal SEL is supplied to the other input terminal IT2 of each NAND gates 211.

The NAND gate 211 performs a NAND operation on signal SINx and signal SEL.

The NAND gate 211 outputs a result of the NAND operation as signal bINLS.

The inverter 215 receives signal bINLS (a result of the NAND operation). The inverter 215 outputs an inverted signal INLS of signal bINLS.

Where the signal level of control signal SEL is at the “L” level and the signal level of signal SINx is at the “L” level, the NAND gate 211 outputs “H” level signal bINLS (bINLS1, bINLS2, . . . , bINLS). The inverter 215 outputs “L” level signal INLS.

Where the signal level of control signal SEL is at the “L” level and the signal level of signal SINx is at the “H” level, the NAND gate 211 outputs “H” level signal bINLS (bINLS1, bINLS2, . . . , bINLS). The inverter 215 outputs “L” level signal INLS.

In this manner, where the signal level of signal SEL is at the “L” level, the NAND gate 211 outputs “H” level signal bINLS regardless of the signal level of signal SINx. The inverter 215 outputs inverted signal INLS (INLS1, INLS2, . . . , INLSn) of signal bINLS supplied from the NAND gate 211.

As a result, where the signal level of control signal SEL is at the “L” level, the logic gate circuit 210 supplies signal INLS having the “L” level and signal bINLS having the “H” level to the level shifter 120.

Where the signal level of control signal SEL is at the “H” level and the signal level of signal SINx is at the “L” level, the NAND gate 211 outputs “H” level signal bINLS. The inverter 215 outputs “L” level signal INLS.

Where the signal level of control signal SEL is at the “H” level and the signal level of signal SINx is at the “H” level, the NAND gate 211 outputs “L” level signal bINLS. The inverter 215 outputs “H” level signal INLS.

In this manner, where the signal level of signal SEL is at the “H” level, the NAND gate 211 outputs inverted signal bINLS of signal SINx. The inverter 215 outputs inverted signal INLS of signal bINLS supplied from the NAND gate 211.

As a result, where the signal level of control signal SEL is at the “H” level, the logic gate circuit 210 supplies signal INLS having the same signal level as signal SINx and signal bINLS having the opposite signal level to signal INLS to the corresponding level shifter 120.

<Level Shifter>

FIGS. 4 to 7 are schematic diagrams showing an example of a level shifter employed in the semiconductor device of the present embodiment.

FIG. 4 shows an example of the configuration of the level shifter of the level shift circuit.

As shown in FIG. 4, the level shifter 120 includes a first coupling circuit 121, a second coupling circuit 122, two inverters 125 (125a and 125b), and one output circuit 127.

One input terminal of the first coupling circuit 121 is connected to one output terminal of the logic gate circuit 210 (output terminal OT2 of the inverter 215). The other input terminal of the first coupling circuit 121 is connected to the other output terminal of the logic gate circuit 210 (output terminal OT1 of the NAND gate 211). The output terminal of the first coupling circuit 121 is connected to the input terminal IT4a of the inverter 125a.

Power supply voltage VDD2 and ground potential VGND are supplied to the first coupling circuit 121.

FIG. 5 is a diagram showing an example of the internal configuration of the first coupling circuit.

As shown in FIG. 5, the coupling circuit 121 is, for example, a CMOS coupling circuit. The coupling circuit 121 includes two P-type field effect transistors PM2 and PM3 and two N-type field effect transistors NM2 and NM3. In the description below, a field effect transistor (for example, a MOS transistor) will be described simply as a transistor.

One end (one of two source/drains) of the current path of P-type transistor PM2 is connected to the power supply terminal 92. The power supply terminal 92 is a terminal to which power supply voltage VDD2 is supplied. The other end (the other of the two source/drains) of the current path of P-type transistor PM2 is connected to the output terminal 85a of the coupling circuit 121 via node NDa. The gate of P-type transistor PM2 is connected to node NDb.

One end of the current path of P-type transistor PM3 is connected to the power supply terminal 92. The other end of the current path of P-type transistor PM3 is connected to node NDb. The gate of P-type transistor PM3 is connected to the output terminal 85a via node NDa.

One end of the current path of N-type transistor NM2 is connected to the ground terminal 98. The ground terminal 98 is a terminal to which ground potential VGND is supplied. The other end of the current path of N-type transistor NM2 is connected to the output terminal 85a via node NDa. The gate of N-type transistor NM2 is connected to the input terminal 81a of the coupling circuit 121.

One end of the current path of N-type transistor NM3 is connected to the ground terminal 98. The other end of the current path of N-type transistor NM3 is connected to node NDb. The gate of N-type transistor NM3 is connected to the other input terminal 82a the coupling circuit 121.

When “H” level signal INLS and “L” level signal bINLS are supplied to the coupling circuit 121, N-type transistor NM2 is set to the on state and N-type transistor NM3 is set to the off state. Node NDa is connected to the ground terminal 98 through transistor NM2 that is in the on state. Node NDb is electrically disconnected from the ground terminal 98 by N-type transistor NM3 that is in the off state.

The potential of node NDa becomes approximately equal to ground potential VGND. P-type transistor PM3 is set to the on state by ground potential VGND supplied to node NDa.

The potential of node NDb rises to approximately the potential (positive potential) of terminal 92 because of P-type transistor PM3 in the on state and N-type transistor NM3 in the off state. As a result, P-type transistor PM2 is set to the off state.

Node NDb is electrically connected to terminal 92 by P-type transistor PM2 in the on state, and is electrically disconnected from the ground terminal 98 by N-type transistor NM2 in the off state.

In this manner, where “H” level signal INLS and “L” level signal bINLS are supplied, node NDa is set to the “L” level, and node NDb is set to the “H” level. As a result, the coupling circuit 121 outputs “L” level signal SLS1 corresponding to the voltage value of ground potential VGND.

When “L” level signal INLS and “H” level signal bINLS are supplied to the coupling circuit 121, N-type transistor NM2 is set to the off state and N-type transistor NM3 is set to the on state. Node NDa is electrically disconnected from the ground terminal 98 by N-type transistor NM2 that is in the off state. Node NDb is electrically connected to the ground terminal 98 by N-type transistor NM3 that is in the on state.

The potential of node NDb becomes approximately equal to ground potential VGND. P-type transistor PM2 is set to the on state by ground potential VGND supplied to node NDb.

The potential of node NDa rises to approximately the potential (positive potential) of terminal 92 because of P-type transistor PM2 in the on state and N-type transistor NM2 in the off state. As a result, P-type transistor PM3 is set to the off state.

Node NDb is electrically disconnected from terminal 92 by P-type transistor PM3 in the off state, and is electrically connected to the ground terminal 98 by N-type transistor NM3 in the on state.

As a result, where “L” level signal INLS and “H” level signal bINLS are supplied, the coupling circuit 121 outputs “H” level signal SLS1 corresponding to the voltage value of power supply voltage VDD2.

Thus, in the coupling circuit 121, the signal level of signal SLS1 is set in accordance with the signal levels of signal INLS and signal bINLS.

As shown in FIG. 4, one input terminal of the second coupling circuit 122 is connected to one output terminal of the logic gate circuit 210 (the output terminal OT2 of the inverter 215). The other input terminal of the second coupling circuit 122 is connected to the other output terminal of the logic gate circuit 210 (output terminal OT1 of the NAND gate 211). The output terminal of the second coupling circuit 122 is connected to the input terminal IT4b of the inverter 125b.

Power supply voltage VSS is supplied to second coupling circuit 122.

FIG. 6 is a diagram showing an example of the internal configuration of the second coupling circuit.

As shown in FIG. 6, the coupling circuit 122 is, for example, a CMOS coupling circuit. The coupling circuit 122 includes two P-type transistors PM4 and PM5 and two N-type transistors NM4 and NM5.

One end of the current path of P-type transistor PM4 is connected to one input terminal 81b of the coupling circuit 122. The other end of the current path of P-type transistor PM4 is connected to node NDc. The gate of P-type transistor PM4 is connected to the ground terminal 98.

One end of the current path of P-type transistor PM5 is connected to the other input terminal 82b of the coupling circuit 122. The other end of the current path of P-type transistor PM5 is connected to the output terminal 85b of the coupling circuit 122 via node NDd. The gate of P-type transistor PM5 is connected to the ground terminal 98.

One end of the current path of N-type transistor NM4 is connected to the power supply terminal 99. The power supply terminal 99 is a power supply terminal to which a negative power supply voltage VSS (or a voltage of 0V or less) is supplied. The other end of the current path of N-type transistor NM4 is connected to node NDc. The gate of N-type transistor NM4 is connected to the output terminal 85b via node NDd.

One end of the current path of N-type transistor NM5 is connected to the power supply terminal 99. The other end of the current path of N-type transistor NM5 is connected to the output terminal 85b via node NDd. The gate of N-type transistor NM3 is connected to node NDc.

Where “H” level signal INLS and “L” level signal bINLS are supplied to the coupling circuit 122, an “H” level signal is supplied to node NDc via P-type transistors PM4 in the on state, and an “L” level signal is supplied to node NDd. Thus, N-type transistor NM5 is set to the on state, and N-type transistor NM4 is set to the off state.

Node NDd is connected to the power supply terminal 99 via transistor NM5 in the on state. Node NDc is electrically disconnected from the power supply terminal 99 by N-type transistor NM4 that is in the off state.

The potential of node NDd becomes approximately equal to the potential of the terminal 99 (for example, 0V or less). Node NDc is kept at a voltage corresponding to the “H” level (for example, voltage VDD1) by the P-type transistor PM4 that is in the on state.

As a result, the coupling circuit 122 outputs “L” level signal SLS2 corresponding to the voltage value of voltage VSS.

Where “L” level signal INLS and “H” level signal bINLS are supplied to the coupling circuit 122, an “L” level signal is supplied to node NDc and an “H” level signal is supplied to node NDd, via P-type transistor PM5 in the on state. Thus, N-type transistor NM4 is set to the on state, and N-type transistor NM5 is set to the off state.

Node NDc is connected to the power supply terminal 99 via transistor NM4 in the on state. Node NDd is electrically disconnected from the power supply terminal 99 by N-type transistor NMS that is in the off state.

The potential of node NDc becomes approximately equal to the potential of terminal 99 (for example, 0V or less). Node NDd is kept at a voltage corresponding to the “H” level (for example, voltage VDD1) by the P-type transistor PM5 that is in the on state.

As a result, the coupling circuit 122 outputs “H” level signal SLS2 corresponding to the voltage value of power supply voltage VDD1.

Thus, in the coupling circuit 122, the signal level of signal SLS2 is set in accordance with the signal levels of signal INLS and signal bINLS.

As shown in FIG. 4, the input terminal IT4a of the inverter 125a is connected to the output terminal of the coupling circuit 121 (for example, terminal 85a shown in FIG. 5). The output terminal OT3a of the inverter 125a is connected to node NDe of the output circuit 127. One voltage terminal of the inverter 125a is connected to the power supply terminal 92. The other voltage terminal of the inverter 125a is connected to the ground terminal 98.

Power supply voltage VDD2 and ground potential VGND are supplied to inverter 125a. As a result, an output signal of the inverter 125a attains a signal level corresponding to the voltage value of power supply voltage VDD2 or a signal level corresponding to the voltage value of ground potential VGND.

The input terminal IT4b of the inverter 125b is connected to the output terminal of the coupling circuit 122 (for example, terminal 85b shown in FIG. 6). The output terminal OT3b of the inverter 125b is connected to node NDf of the output circuit 127. One voltage terminal of the inverter 125b is connected to the ground terminal 98. The other voltage terminal of the inverter 125a is connected to the power supply terminal 99.

Power supply voltage VSS and ground potential VGND are supplied to the inverter 125b. As a result, an output signal of the inverter 125b attains a signal level corresponding to the voltage value of power supply voltage VSS or a signal level corresponding to the voltage value of ground potential VGND.

FIG. 7 is a diagram showing an example of the internal configuration of an inverter. The voltages supplied to the two inverters 125a and 125b shown in FIG. 4 are different, but the internal configuration of the inverter 125a is substantially the same as the internal configuration of the inverter 125b. Thus, the internal configuration of the inverter 125 will be described without distinction between the two inverters 125a and 125b.

As shown in FIG. 7, inverter 125 (125a and 125b) includes P-type transistor PMS and N-type transistor NM6.

One end of the current path of P-type transistor PM6 is connected to the voltage terminal 95. The other end of the current path of P-type transistor PMS is connected to the output terminal 86 (OT3a and Ot3b). The gate of P-type transistor PM6 is connected to the input terminal 85 (IT4a and IT4b).

One end of the current path of N-type transistor NM6 is connected to the voltage terminal 96. The other end of the current path of N-type transistor NM6 is connected to the output terminal 86 of the inverter 125. The gate of N-type transistor NM6 is connected to the input terminal 85 of the inverter 125.

Where inverter 125 shown in FIG. 7 is employed as inverter 125a shown in FIG. 4, power supply voltage VDD2 is applied to voltage terminal 95 and ground potential VGND is applied to voltage terminal 96. The input terminal 85 (IT4a) is connected to the output terminal 85a of circuit 121 shown in FIG. 5. The output terminal 86 (OT3a) is connected to node NDe of the output circuit 127.

Where inverter 125 shown in FIG. 7 is employed as inverter 125b shown in FIG. 4, ground potential VGND is applied to voltage terminal 95 and power supply voltage VSS is applied to voltage terminal 96. The input terminal 85 (IT4b) is connected to the output terminal 85b of circuit 122 shown in FIG. 6. The output terminal 86 (OT3b) is connected to node NDf of the output circuit 127.

As shown in FIG. 4, the output circuit 127 includes P-type transistor PM1 and N-type transistor NM1.

One end (one of two source/drains) of the current path of P-type transistor PM1 is connected to the output terminal OT3a of the inverter 125a via node NDe. The other end (the other of two source/drains) of the current path of P-type transistor PM1 is connected to node NDg. The gate of P-type transistor PM1 is connected to ground terminal 98 via node NDh.

One end (one of two source/drains) of the current path of N-type transistor NM1 is connected to the output terminal OT3b of the inverter 125b via node NDf. The other end (the other of two source/drains) of the current path of N-type transistor NM1 is connected to node NDg. The gate of N-type transistor NM1 is connected to ground terminal 98 via node NDh.

The other ends of the current paths of N-type and P-type transistors NM1 and PM1 are connected to the corresponding second logic circuits 130 via node NDg. Signal OUTLS of the level shifter 120 is supplied to the logic circuit 130 from node NDg.

Ground potential VGND is supplied to the gates of the N-type and P-type transistors NM1 and PM1.

Where signal SLS1 is an “L” level signal and signal SLS2 is an “L” level signal, P-type transistor PM1 is set to the on state and N-type transistor NM1 is set to the off state, according to the potential difference between the gate and the source. As a result, signal OUTLS of the signal level corresponding to voltage VDD2 is output from the output circuit 127 via P-type transistor PM1 that is in the on state. At this time, a positive charge is accumulated at node NDg of the output circuit 127 from the terminal of power supply voltage VDD2 via P-type transistor PM1 in the on state.

Where signal SLS1 is an “H” level signal and signal SLS2 is an “H” level signal, P-type transistor PM1 is set to the off state and N-type transistor NM1 is set to the on state, according to the potential difference between the gate and the source. As a result, signal OUTLS of the signal level corresponding to voltage VSS is output from the output circuit 127 via N-type transistor NM1 that is in the on state. At this time, node NDg of the output circuit 127 is discharged by N-type transistor NM1 in the on state. In other words, a negative charge is accumulated at node NDg of the output circuit 127 from the terminal of power supply voltage VSS via N-type transistor NM1 in the on state.

(c) Operation Example

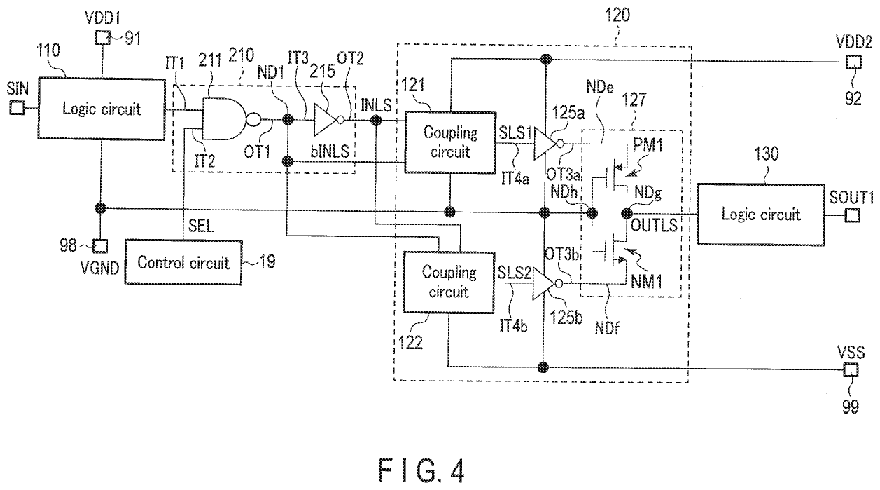

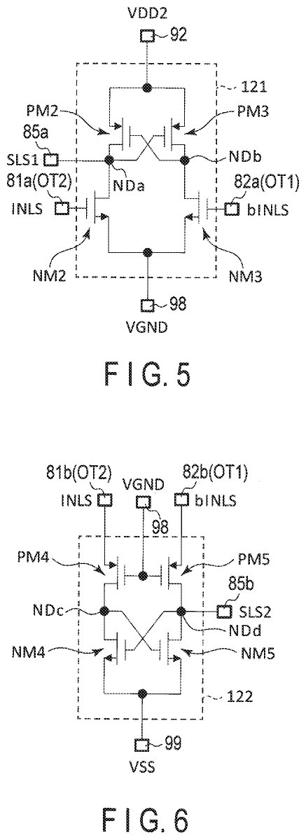

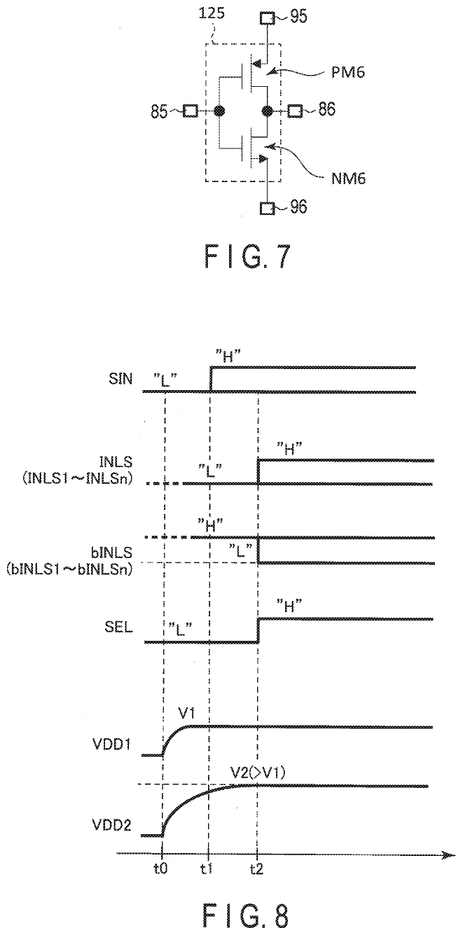

An operation example of the semiconductor device of the present embodiment will be described with reference to FIG. 8

The operation example of the semiconductor device of the present embodiment will be described using FIG. 1 to FIG. 7 as appropriate. Further, a description will be given as to how control for reducing the load capacity is performed in the present embodiment when a positive power supply voltage is generated.

FIG. 8 is a timing chart for illustrating the operation example of the semiconductor device of the present embodiment.

<Time t0>

As shown in FIG. 8, at the time of activation of the semiconductor device 1, first power supply voltage VDD1 and ground potential VGND are supplied to the semiconductor device 1 at time t0. Power supply voltage VDD1 has, for example, a voltage value V1 (>0V).

The control circuit 19 controls the operation of each circuit provided in the semiconductor device 1.

Power supply voltage VDD1 is supplied to the first internal circuit 11, the state determining circuit 21, the level shift circuit 12, the booster circuit 16, etc. Ground potential VGND is supplied to the first internal circuit 11, the state determining circuit 21, the level shift circuit 12, the step-down circuit 17, etc.

The booster circuit 16 causes the charge pump circuit to start boosting a voltage, using power supply voltage VDD1. The step-down circuit 17 causes the charge pump circuit to start stepping down a voltage, using ground potential VGND.

In the standby period, the control circuit 19 sets the signal level of control signal SEL to the “L” level as an initial state of the activation process of the semiconductor device 1. For example, the control circuit 19 causes the monitor circuit 191 to monitor a voltage value of the voltage generated by the booster circuit 16 and a voltage value of the voltage generated by the step-down circuit 17. Where the voltages generated by the voltage booster circuit 16 and the voltage step-down circuit 17 have not reached predetermined voltage values, the control circuit 19 supplies control signal SEL of the “L” level to the state determining circuit 21.

<Time t1>

After the semiconductor device 1 is activated, signal (data) SIN is supplied at time t1, for example. The first logic circuit 110 of the first internal circuit 11 receives signal SIN.

Signal SIN has a signal level of either the “H” level or the “L” level. The “H” level voltage value corresponds to voltage VDD1, and the “L” level voltage value corresponds to ground potential VSS.

Logic circuit 110 supplies signal SINx obtained based on signal SIN to the state determining circuit 21.

During the standby period, the control circuit 19 keeps the signal level of control signal SEL at the “L” level when the voltages generated by booster circuit 16 and step-down circuit 17 and being monitored have not reached predetermined voltage values.

In the logic gate circuits 210 of the state determining circuit 21 (see FIGS. 3 and 4, for example), when control signal SEL of the “L” level is supplied, the NAND gates 211 output signal bINLS of the “H” level and the inverters 215 output signal INLS of the “L” level. At this time, all the logic gate circuits 210 supplied with control signal SEL of the “L” level output the same signals (i.e., signal INLS of the “L” level and signal bINLS of the “H” level).

The coupling circuits 121 and 122 of the level shift circuit 12 receive signal INLS of the “L” level and signal bINLS of the “H” level.

In the coupling circuit 121 shown in FIG. 5, when signal INLS of the “L” level and signal bINLS of the “H” level are supplied, the coupling circuit 121 outputs signal SLS1 of the “H” level corresponding to power supply voltage VDD2, as described above. An “L” level signal corresponding to ground potential VGND is supplied to the output circuit 127 via inverter 125a.

In the coupling circuit 122 shown in FIG. 6, when signal INLS of the “L” level and signal bINLS of the “H” level are supplied, the coupling circuit 122 outputs signal SLS2 of the “H” level corresponding to power supply voltage VDD1, as described above. An “L” level signal corresponding to power supply voltage VSS is supplied to the output circuit 127 via inverter 125b.

Therefore, the plurality of level shifters 120 of the level shift circuit 12 output signal SOUT corresponding to voltage VSS.

At this time, the output terminal of the level shifter 120 (i.e., node NDh of the output circuit) is electrically disconnected from the terminal of power supply voltage VDD2 by the P-type transistor PM1 in the off state.

As a result, the level shift circuit 12 is set to a non-active state with respect to the power supply line to which the power supply voltage VDD2 is supplied (a state electrically isolated from power supply line).

<Time t2>

At time t2, generated voltage VDD2 of the booster circuit 16 reaches predetermined voltage value V2 (>V1). In addition, generated voltage VSS of the step-down circuit 17 reaches a predetermined voltage value.

The control circuit 19 activates circuits 13 and 14 that can operate on voltages VDD2 and VSS, based on the monitoring result of generated voltage VDD2.

The control circuit 19 changes the signal level of control signal SEL from the “L” level to the “H” level. As a result, at time t2, the standby state of the semiconductor device 1 ends. That is, the activation process of the semiconductor device 1 is completed.

The state determining circuit 21 receives control signal SEL of the “H” level. In response to control signal SEL of the “H” level, the logic gate circuit 210 transfers a signal supplied from the logic circuit 110 to the level shift circuit 12. Simultaneously, the state determining circuit 21 causes the level shift circuit 12 to transition to the activated state with respect to power supply voltage VDD2.

The level shift circuit 12 receives signals INLS and bINLS. Supplied with signals INLS and bINLS, the level shifters 120 output signal OUTLS corresponding to the signal level of signal INLS.

The “H” level of signal OUTLS corresponds to the voltage value of power supply voltage VDD2, and the “L” level of signal OUTLS corresponds to the voltage value of power supply voltage VSS.

The voltage values of the voltages generated by the booster circuit and the step-down circuit may momentarily fluctuate at the timing when the plurality of level shifters 120 are electrically connected to the terminal of power supply voltage VDD2. In practice, however, this fluctuation of the voltage values does not give rise to any malfunction of the operation.

The second internal circuit 13 receives signal OUTLS from the level shift circuit 12. In the second internal circuit 13, each second logic circuit 130 performs calculation processing and/or control processing using signal OUTLS supplied from the corresponding level shifter 120. The second logic circuit 130 outputs signal SIG based on the processing result. The “H” level of signal SIG corresponds to the voltage value of power supply voltage VDD2, and the “L” level of signal SIG corresponds to the voltage value of power supply voltage VSS.

The third internal circuit 14 executes calculation processing and/or control operation using signal SIG supplied from the second internal circuit 13.

In the manner described above, the semiconductor device of the present embodiment performs its operation.

(d) Summary

There may be a case where the internal circuits of a semiconductor device are operated using a voltage higher than the voltage supplied from outside the semiconductor device, in order to improve the characteristics of the semiconductor device, as in the case where the on-resistance of a field effect transistor of the semiconductor device is lowered and/or the case where the parasitic capacitance is reduced.

For this reason, the voltage value corresponding to the signal level of a signal used in the semiconductor device may be different from the voltage value corresponding to the signal level of the signal supplied from outside the semiconductor device. In this case, the level shifters (level shift circuit) of the semiconductor device convert the voltage value of the signal level of the signal supplied from outside the semiconductor device into the voltage value of the signal level used in the semiconductor device.

If a plurality of level shifters are connected to the same voltage terminal (and to the booster circuit or step-down circuit), the plurality of level shifters may be the load capacitance for that terminal and other circuits. Due to this load capacitance, degradation of the characteristics of the semiconductor device, such as an operation delay, may occur. For example, due to the load capacitance caused by the level shifters, the booster circuit and the step-down circuit may require a longer period for boosting or stepping down a voltage to a predetermined voltage value.

The semiconductor device of the present embodiment causes the state determining circuit to keep a plurality of level shifters in the inactive state during a standby period which is from the time when the activation process of the semiconductor device is started (a voltage is applied) to the time when the internal circuits become operable (for example, the period from the time when the boosting of a voltage is started by the booster circuit to the time when that voltage becomes a predetermined voltage, and/or the period from the time when the lowering of a voltage is started by the step-down circuit to the time when that voltage becomes a predetermined voltage).

As a result, in the semiconductor device of the present embodiment, the level shifters are electrically disconnected from the power supply terminal and other circuits (for example, the booster circuit and the step-down circuit) during the generation of a voltage by the booster circuit or the step-down circuit.

After power supply voltage VDD2 and/or power supply voltage VSS have reached predetermined voltage values (after the standby period has elapsed), the level shifters are activated by the state determining circuit 21 and are thus electrically connected to a positive power supply terminal (and the booster circuit 16) and/or to a negative (or 0V) power supply terminal (and the step-down circuit 17).

Accordingly, in the present embodiment, the load capacitance caused by the level shifters is reduced at the time of the activation of the semiconductor device.

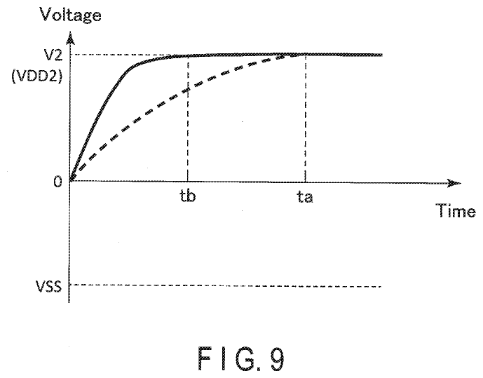

FIG. 9 is a graph showing operating characteristics of the semiconductor device of the present embodiment.

The graph of FIG. 9 shows how the output characteristics of the booster circuit of the semiconductor device of the present embodiment are where the voltage generation period by the booster circuit (boost period) is dominant for the activation time of the semiconductor device.

In FIG. 9, the horizontal axis of the graph corresponds to time, and the vertical axis of the graph corresponds to the voltage value. In FIG. 9, the solid line indicates the characteristics of the semiconductor device of the present embodiment, and the dashed line indicates the characteristics of a semiconductor device of a comparative example.

As shown in FIG. 9, the semiconductor device of the comparative example reaches predetermined voltage value V2 at time ta. Due to the load capacitance, the voltage generated by the booster circuit requires a relatively long period to reach the predetermined voltage value V2.

On the other hand, the semiconductor device of the present embodiment reaches the predetermined voltage value V2 at time tb earlier than time ta. That is, the booster circuit of the semiconductor device of the present embodiment can generate predetermined voltage VDD2 in a period shorter than that of the comparative example.

Thus, the semiconductor device off the present embodiment can suppress an increase in the period in which the voltage is boosted to a predetermined voltage value. As a result, the semiconductor device of the present embodiment can improve the operating speed.

As described above, the semiconductor device of the first embodiment can improve the characteristics of the semiconductor device.

### (2) Second Embodiment

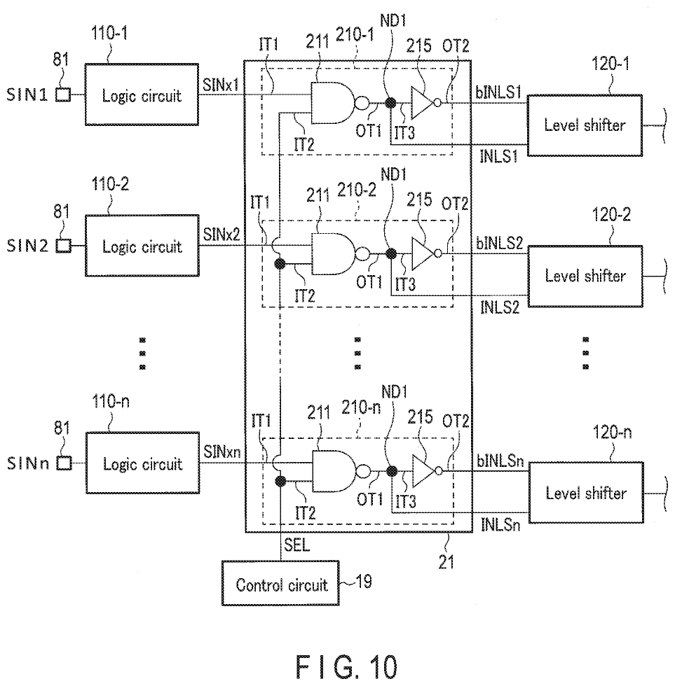

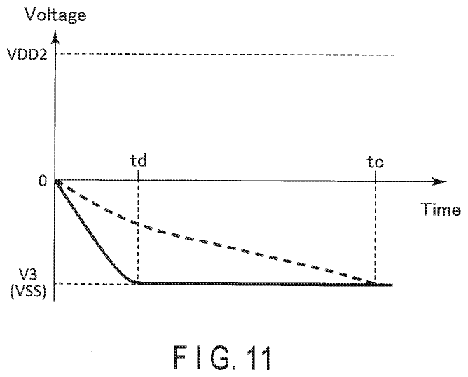

A semiconductor device of the second embodiment will be described with reference to FIG. 10 and FIG. 11.

FIG. 10 is a schematic diagram showing an internal configuration of the semiconductor device of the present embodiment.

Depending on the circuit configuration of the semiconductor device, the period for generating a negative power supply voltage may be dominant for the activation time (operating speed) of the semiconductor device.

In this case, the semiconductor device of the present embodiment sets the signal level of signal INLS to the “H” level and sets the signal level of signal bINLS to the “L” level in an initial state of the state determining circuit 21.

As shown in FIG. 10, in the state determining circuit 21 of the semiconductor device of the present embodiment, the logic gate circuit 210 outputs signal bINLS from the output terminal of the inverter 215 and outputs signal INLS from the output terminal of the NAND gate 211.

The output terminal of the inverter 215 is connected to terminal 82a of coupling circuit 121 shown in FIG. 5 and to terminal 82b of coupling circuit 122 shown in FIG. 6. The output terminal of the NAND gate 211 is connected to terminal 81a of coupling circuit 121 shown in FIG. 5 and to terminal 81b of coupling circuit 122 shown FIG. 6.

The operation of the semiconductor device 1 of the present embodiment will be described. The signal level of control signal SEL is set to the “L” level in the initial state (standby period) which is from the time when the power supply voltage is applied and lasts a predetermined time (the time required for voltage VSS to reach a predetermined voltage value).

The signal level of signal INLS is set to the “L” level, and the signal level of signal bINLS is set to the “H” level.

At this time, in the output circuit 127 shown in FIG. 4, the output terminal of the level shifter 120 (node NDh of the output circuit) is electrically disconnected from the terminal of power supply voltage VSS by N-type transistor NM1 that is in the off state.

After completion of the activation process of the semiconductor device (at a certain time during the standby period), the control circuit 19 sets the signal level of control signal SEL to the “H” level. Thereby, the signal level of signal INLS is set to the “H” level, and the signal level of signal bINLS can take a signal level determined in accordance with signal SINx. Therefore, the level shifter 120 outputs a signal having a signal level corresponding to power supply voltage VDD2 or power supply voltage VSS.

FIG. 11 is a graph showing how the output characteristics of the step-down circuit of the semiconductor device of the present embodiment are, where the voltage generation period by the step-down circuit (step-down period) is dominant for the activation time of the semiconductor device.

In FIG. 11, the horizontal axis of the graph corresponds to time, and the vertical axis of the graph corresponds to the voltage value. In FIG. 11, the solid line indicates the characteristics of the semiconductor device of the present embodiment, and the dashed line indicates the characteristics of a semiconductor device of a comparative example.

As shown in FIG. 11, the step-down circuit of the semiconductor device of the present embodiment can generate power supply voltage VSS having predetermined voltage value V3 in a period (time td) shorter than that (time tc) of the comparative example.

Thus, the semiconductor device of the present embodiment can reduce the influence which the generation period of the negative power supply voltage may have on the activation time of the semiconductor device.

Therefore, the semiconductor device of the second embodiment can have substantially the same advantages as the semiconductor device of the first embodiment.

As described above, the semiconductor device of the second embodiment can improve the characteristics.

### (3) Third Embodiment

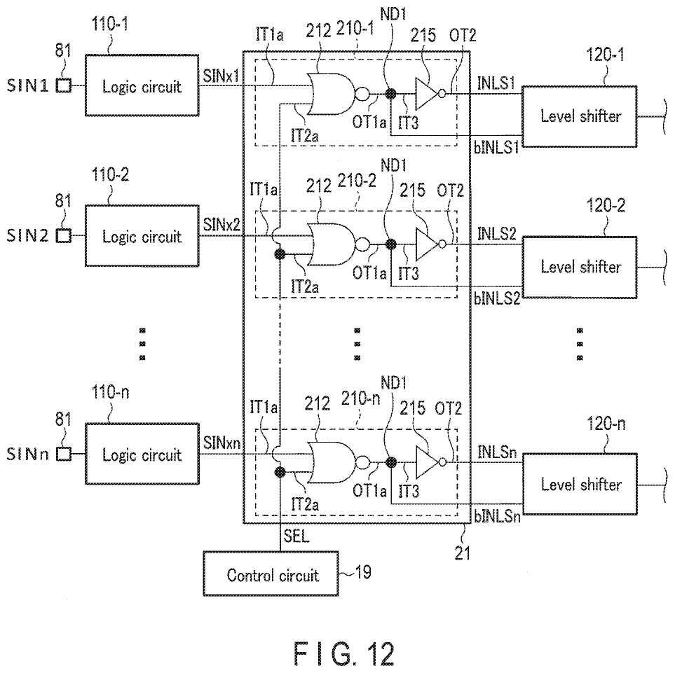

A semiconductor device of the third embodiment will be described with reference to FIG. 12.

FIG. 12 is a schematic diagram showing a configuration example of the state determining circuit of the semiconductor device of the present embodiment.

As shown in FIG. 12, each of the logic gate circuits 210 of the state determining circuit 21 includes an NOR gate 212 and an inverter 215. The NOR gate 212 has two input terminals IT1a and IT2a and one output terminal OT1a.

One input terminal IT1a of the NOR gate 212 is connected to the first logic circuit 110. The other input terminal IT2a of the NOR gate 212 is connected to the control circuit 19. The output terminal OT1a of the NOR gate 212 is connected to the input terminal IT3 of the inverter 215 and to the level shift circuit 12. The output terminal of the inverter 215 is connected to the level shift circuit 12.

The output terminal OT2 of the inverter 215 is connected to terminal 81a of coupling circuit 121 shown in FIG. 5, and to terminal 81b of coupling circuit 122 shown in FIG. 6. The output terminal OT1a of the NOR gate 212 is connected to terminal 81a of coupling circuit 121 shown in FIG. 5 and to terminal 82b of coupling circuit 122 shown FIG. 6.

Signal SINx is supplied to one input terminal IT1a of the NOR gate 212. Signal SEL is supplied to the other input terminal IT2a of the NOR gate 212.

The NOR gate 212 performs a NOR operation on signal SINx and signal SEL. The inverter 215 outputs an inverted signal of an output signal of the NOR gate 212 (a result of the NOR operation).

Where the signal level of control signal SEL is at the “L” level and the signal level of signal SINx is at the “L” level, the NOR gate 212 outputs “H” level signal bINLS. The inverter 215 outputs “L” level signal INLS.

Where the signal level of control signal SEL is at the “L” level and the signal level of signal SINx is at the “H” level, the NOR gate 212 outputs “L” level signal bINLS. The inverter 215 outputs “H” level signal INLS.

Where the signal level of control signal SEL is at the “H” level and the signal level of signal SINx the “L” level, the NOR gate 212 outputs “L” level signal bINLS. The inverter 215 outputs “H” level signal INLS.

Where the signal level of control signal SEL is at the “H” level and the signal level of signal SINx is at the “H” level, the NOR gate 212 outputs “L” level signal bINLS. The inverter 215 outputs “H” level signal INLS.

For example, where the voltage boosting period by the booster circuit is dominant for the activation time of the semiconductor device, the control circuit 19 sets the signal level of control signal SEL to the “H” level in the initial state (i.e., a state in which the semiconductor device is turned on). As a result, the output terminals of the plurality of level shifters 120 are electrically disconnected from the power supply terminal 92 to which power supply voltage VDD2 is supplied. This alleviates the load capacitance which the level shifters may cause for the booster circuit.

The control circuit 19 detects that the potential of the power supply terminal 92 has reached a predetermined voltage value (for example, the voltage value of power supply voltage VDD2) at a certain time during the standby period. The control circuit 19 changes the signal level of control signal SEL from the “H” level to the “L” level based on the result of monitoring the potential of the power supply terminal. As a result, the plurality of level shifters 120 are electrically connected to the power supply terminal 92 (and the booster circuit 16).

As a result, the level shifters 120 and internal circuits 13 and 14 operate in the semiconductor device 1 of the present embodiment.

As described above, the semiconductor device of the present embodiment can reduce the influence which the load capacitance may have on circuits in the semiconductor device (for example, the booster circuit).

Therefore, the semiconductor device of the third embodiment can have substantially the same advantages as the semiconductor devices of the first and second embodiments.

### (4) Fourth Embodiment

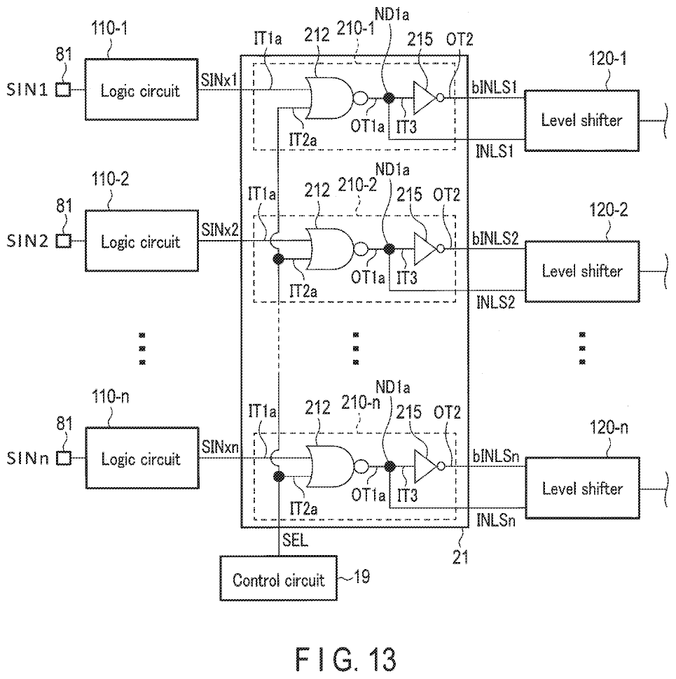

A semiconductor device of the fourth embodiment will be described with reference to FIG. 13.

FIG. 13 is a schematic diagram showing a configuration example of the state determining circuit of the semiconductor device of the present embodiment.

As described in connection with the second embodiment, the period for generating a negative power supply voltage may be dominant for the operation of the semiconductor device.

In this case, the semiconductor device of the present embodiment sets the signal level of signal INLS to the “H” level and sets the signal level of signal bINLS to the “L” level in an initial state of the state determining circuit including a NOR gate.

As shown in FIG. 13, where a NOR gate 212 is employed in the logic gate circuit in the state determining circuit of the semiconductor device of the present embodiment, signal bINLS is output from the output terminal OT2 of the inverter 215 and signal INLS is output from the output terminal OT1a of the NOR gate 212.

In this case, the output terminal OT2 of the inverter 215 is connected to terminal 82a of coupling circuit 121 shown in FIG. 5, and to terminal 82b of coupling circuit 122 shown in FIG. 6. The output terminal OT1a of the NOR gate 212 is connected to terminal 81a of coupling circuit 121 shown in FIG. 5 and to terminal 81b of coupling circuit 122 shown FIG. 6.

Where the voltage step-down period by the step-down circuit is dominant for the activation time of the semiconductor device, the control circuit 19 sets the signal level of control signal SEL to the “H” level in the initial state. As a result, the output terminals of the plurality of level shifters 120 are electrically disconnected from the power supply terminal 99 to which power supply voltage VSS is supplied (and from the step-down circuit 17).

The control circuit 19 detects that the monitored potential of the power supply terminal 99 has reached a predetermined voltage value (for example, voltage value V3 of power supply voltage VSS) at a certain time during the standby period. The control circuit 19 changes the signal level of control signal SEL from the “H” level to the “L” level based on the result of monitoring the potential of the power supply terminal 99. The signal level of signal INLS is set to the signal level of the inverted signal of signal SINx, and the signal level of signal bINLS is set to the same level as the signal level of signal SINx.

As a result, the output terminals of the plurality of level shifters 120 are electrically connected to the power supply terminal 99 of power supply voltage VSS and the step-down circuit 17. As a result, the level shifters 120 and internal circuits 13 and 14 operate in the semiconductor device of the present embodiment.

As described above, the semiconductor device of the fourth embodiment can have substantially the same advantages as the semiconductor devices of the first to third embodiments.

(5) Application Example

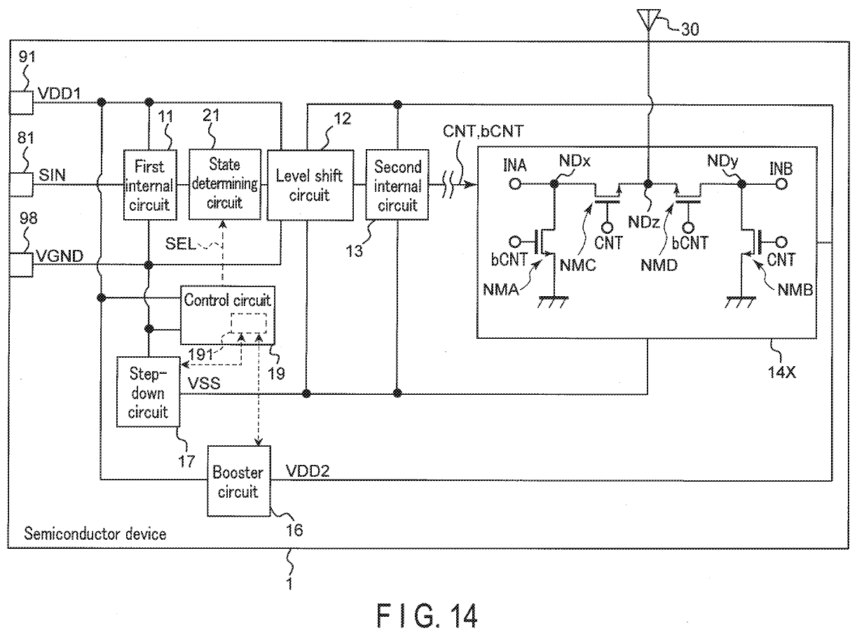

An application example of the semiconductor device of the embodiment will be described with reference to FIG. 14.

The semiconductor device 1 of the embodiment can be applied to an antenna circuit.

FIG. 14 is a diagram showing an application example of the semiconductor device of the embodiment.

As shown in FIG. 14, the third internal circuit 14X is an antenna switch control circuit. The second internal circuit 13 is, for example, a switch control circuit.

The antenna switch control circuit 14X includes four N-type transistors NMA, NMB, NMC and NMD.

One end of the current path of N-type transistor NMA is connected to the ground terminal. The other end of the current path of N-type transistor NMA is connected to node NDx.

One end of the current path of N-type transistor NMB is connected to the ground terminal. The other end of the current path of N-type transistor NMB is connected to node NDy.

One end of the current path of N-type transistor NMC is connected to node NDx. The other end of the current path of N-type transistor NMC is connected to node NDz.

One end of the current path of N-type transistor NMD is connected to node NDy. The other end of the current path of N-type transistor NMD is connected to node NDz.

Node NDx is connected to terminal 86A. Signal INA is supplied to terminal 86A. Node NDy is connected to terminal 86B. Signal INB is supplied to terminal 86B. Node NDz is connected to an antenna 30.

Control signal CNT is supplied to the gate of transistor NMB and the gate of transistor NMC. Control signal bCNT is supplied to the gate of transistor NMA and the gate of transistor NMD. Control signal bCNT has a complementary relationship with control signal CNT. For example, control signals CNT and bCNT are generated using signal SIG.

Control signals CNT and bCNT are supplied from internal circuit 13 serving as a switch control circuit (for example, a high frequency switch circuit).

Transistors NMA, NMB, NMC and NMD are switched on and off by control signals CNT and bCNT. Thereby, an oscillation signal using signal INA and signal INB is output from the antenna 30.

The activation process of the antenna switch control circuit, an example of the semiconductor device of the present embodiment, can be completed in a relatively short period of time. Therefore, the activation time and/or switching time of the antenna switch control circuit, which is the example of the semiconductor device of the present embodiment, is improved.

The semiconductor device of the present embodiment may be applied to devices other than the antenna circuit.

For example, the semiconductor device of the present embodiment can be applied to a multi-port switch circuit, a high-speed transmission circuit, or a multiple input/multiple output circuit.

As a more specific example, the semiconductor device of the present embodiment may be applied to a memory system, such as an interface circuit (input/output circuit) of a NAND flash, memory, an interface circuit of a memory controller, or the like. In addition, as a more specific example, the semiconductor device of the present embodiment may be applied to an arithmetic circuit (e.g., a CPU), an image processing circuit (e.g., a digital camera), a home appliance, and the like.

(6) Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first circuit transmitting a first signal;
a second circuit receiving a second signal;
a first level shift circuit converting a signal level of the first signal from a value corresponding to a first voltage to a value corresponding to a second voltage which is different from the first voltage, and transmitting the second signal; and
a third circuit receiving the first signal and a control signal, and transmitting a third signal having a fixed signal level to the first level shift circuit when a signal level of the control signal is a first level.

2. The semiconductor device according to claim 1, wherein
the third circuit transmits the first signal to the first level shift circuit when the signal level of the control signal is a second level.

3. The semiconductor device according to claim 1, wherein
the third signal is independent from a signal level of the first signal.

4. The semiconductor device according to claim 1, wherein
the third circuit controls activation of the level shift circuit.

5. The semiconductor device according to claim 1, wherein
the first level shift circuit is electrically disconnected from a terminal to which the second voltage is supplied when the signal level of the control signal is the first level.

6. The semiconductor device according to claim 1, further comprising:
a fourth circuit transmitting a fourth signal;
a fifth circuit receiving a fifth signal;
a second level shift circuit converting a signal level of the fourth signal from a value corresponding to the first voltage to a value corresponding to the second voltage, and transmitting the fifth signal; and
a sixth circuit receiving the fourth signal and the control signal, and transmitting a sixth signal having the fixed signal level to the second level shift circuit when the signal level of the control signal is the first level.

7. The semiconductor device according to claim 6, wherein.
a signal level of the sixth signal is the same as a signal level of the third signal.

8. The semiconductor device according to claim 6, wherein
the third circuit transmits the third signal to the first level shift circuit, and the sixth circuit transmits the fourth signal to the second level shift circuit when the signal level of the control signal is a second level.

9. The semiconductor device according to claim 1, wherein the third circuits includes:
a NAND gate including a first input terminal receiving the first signal, a second input terminal receiving the control signal, and a first output terminal transmitting a first output signal to the first level shift circuit; and
an inverter including a third input terminal receiving the first output signal, and a second output terminal transmitting a second output circuit to the first level shift circuit.

10. The semiconductor device according to claim 1, wherein the third circuits includes:
a NOR gate including a first input terminal receiving the first signal, a second input terminal receiving the control signal, and a first output terminal transmitting a first output signal to the first level shift circuit; and
an inverter including a third input terminal receiving the first output signal, and a second output terminal transmitting a second output circuit to the first level shift circuit.

11. The semiconductor device according to claim 1, wherein the first level shift circuits includes:
a first coupling circuit to which the second voltage and a third voltage lower than the first voltage are supplied;
a second coupling circuit to which the third voltage and a fourth voltage lower than the third voltage are supplied; and
a seventh circuit connected to the first and second coupling circuits,
the first coupling circuit receives a signal from the third circuit, and transmits a third output signal corresponding to one of the second voltage and the third voltage to the seventh circuit based on the signal,
the second coupling circuit receives the signal, and transmits a fourth output signal corresponding to one of the third voltage and the fourth voltage to the seventh circuit based on the signal,
and the seventh circuit transmits the second signal having a value corresponding to one of the second voltage and the fourth voltage based on the third and fourth output signals.

12. The semiconductor device according to claim 1, further comprising:
a voltage generation circuit generating the second voltage, using the first voltage; and
a control circuit transmitting the control signal.

13. The semiconductor device according to claim 12, wherein
the control circuit monitors a voltage value of a generated voltage of the voltage generation circuit, and sets the signal level of the control signal based on a monitoring result of the voltage value of the generated voltage.

14. The semiconductor device according to claim 12, wherein
the first voltage and the second voltage are positive voltages, and
the voltage generation circuit is a booster circuit.

15. The semiconductor device according to claim 12, wherein
the first voltage is a ground potential and the second voltage is a negative voltage, and
the voltage generation circuit is a step-down circuit.

16. The semiconductor device according to claim 1, wherein
the third circuit is an antenna control circuit connected to an antenna.

17. A semiconductor device comprising:
first circuits each transmitting a first signal;
second circuits each receiving a second signal;
level shift circuits each converting a signal level of the first signal from a corresponding first circuit from a value corresponding to a first voltage to a value corresponding to a second voltage different from the first voltage, and transmitting the second signal to a corresponding second circuit; and
third circuits each receiving the first signal from a corresponding first circuit and a control signal, and transmitting a third signal having a fixed signal level to a corresponding level shift circuit when a signal level of the control signal is a first level.

18. The semiconductor device according to claim 17, wherein
each of the third circuits transmits the first signal to the corresponding level shift circuit when the signal level of the control signal is a second level.

19. The semiconductor device according to claim 17, wherein
the third signal is independent from a signal level of the first signal.

20. The semiconductor device according to claim 17, wherein
Each of the third circuits controls activation of the level shift circuits.
